(19) United States
(12) Patent Application Publication
(10) Pub. No.: US 2021/0062940 A1
(43) Pub. Date: Mar. 4, 2021

(54) FLEXIBLE PIPE AND EXHAUST HEATING SYSTEM WITH THE SAME

(71) Applicant: UNION CO., LTD., Cheonan-si (KR)

(72) Inventor: Kyung Sang CHO, Pyeongtaek-si (KR)

(21) Appl. No.: 17/001,019

(22) Filed: Aug. 24, 2020

(30) Foreign Application Priority Data
Aug. 26, 2019 (KR) 10-2019-0104546

(51) Int. Cl. F16L 11/15; F16L 53/38; F16L 11/22

(52) U.S. Cl. CPC F16L 11/15; H01L 21/67017; F16L 11/22; F16L 53/38

(57) ABSTRACT

Disclosed are a flexible pipe and an exhaust heating system with the same. The flexible pipe includes double pipe-structured fixed sections having constant length and straight shape, and at least one flexible section provided between the fixed sections and variable in length and shape, wherein the flexible section is provided as a triple structure including an outer bellows pipe having a shape of a corrugated pipe, an inner bellows pipe provided inside the outer bellows pipe, and an interlock pipe provided inside the inner bellows pipe, and a heater is installed on an inner pipe of the fixed section having the double pipe structure in a fixed section applied to an input end connected to a vacuum pump among the fixed sections to intensively supply heat, so that the powder is prevented from being precipitated inside the flexible pipe.

### CROSS-REFERENCE TO RELATED APPLICATION

This application claims priority to and the benefit of Korean Patent Application No. 10-2019-0104546, filed on Aug. 26, 2019, the disclosure of which is incorporated herein by reference in its entirety.

### BACKGROUND OF THE INVENTION

### 1. Field of the Invention

The present invention relates to a flexible pipe, and more particularly, to a flexible pipe and an exhaust heating system with the same used to connect vacuum lines between components of a semiconductor manufacturing equipment.

### 2. Description of the Related Art

In general, a semiconductor manufacturing process refers to a series of processes that repeatedly perform various processes such as an oxidation process, a diffusion process, a photo process, an etching process, an ion implantation process, a deposition process, and a metal wiring process on a silicon wafer. Most semiconductor manufacturing equipment performing each of the above processes maintain a high vacuum state in order to prevent the properties of a semiconductor device from deteriorating or the yield from decreasing due to foreign substances such as dust particles during the processes.

The most semiconductor manufacturing equipment that require a vacuum environment is installed with a vacuum apparatus for generating a vacuum environment, and the vacuum apparatus largely includes a vacuum pump, a vacuum line, and an exhaust line.

The vacuum line has one side connected to the semiconductor manufacturing equipment, which requires the vacuum environment, and the other side connected to the vacuum pump, in which the exhaust line is connected to one side of the vacuum pump.

Accordingly, the vacuum pump operates to keep the inside of the semiconductor equipment in a vacuum state, and by-products after the process proceeds inside the semiconductor manufacturing equipment are sucked into the vacuum pump through the vacuum line and discharged through the exhaust line.

The vacuum line of the vacuum apparatus is configured to connect the semiconductor manufacturing equipment, which requires the vacuum environment, to the vacuum pump, in which a stretchable and flexible bellows is used, instead of the pipe, at a portion that has a complicated piping of the semiconductor manufacturing equipment, or a portion that requires the flexibility because the vacuum line of the vacuum apparatus cannot be connected only horizontally or vertically due to installation locations of the semiconductor manufacturing equipment and the vacuum apparatus.

Both side ends of a general bellows are coupled to flanges so that the bellows may be connected to an exhaust line, a vacuum pump, a semiconductor process chamber, or the like through the flange.

In other words, a large amount of solid and stretchable by-products are generated in a chamber, fore line, exhaust line, and the like during semiconductor and display etching, chemical vapor deposition (CVD), metal, and diffusion processes. When the above substances are accumulated inside the vacuum pipe, the accumulated substances may cause the deterioration of equipment performance, the decrease of production yield, the contamination of particle sources and inside a chamber due to back stream of additionally accumulated substances.

An etching process following the CVD, during manufacturing a flat display or a semiconductor, is the most basic process for precisely forming a thin film of several layers exhibiting properties of a semiconductor or insulator, and integrally forming a switch pattern of the semiconductor through etching.

In order to induce the above reaction, various process gases supplied to the chamber are used only in small quantities and mostly discharged through the exhaust pipe.

Meanwhile, various process gases react with each other and form powder in the process of discharging the various process gases through the exhaust pipe.

When the powder starts to be precipitated in the pipe, the back pressure in the exhaust pipe increases, thereby disturbing (clogging) smooth exhaust activities, and an unnecessary load is applied to the vacuum pump, thereby shortening a preventive maintenance (PM) cycle. In the worst case, the pump may stop or abnormal operation may occur during the process, and accordingly a silicon wafer or a glass used as a substrate material may be contaminated, thereby causing enormous losses.

To solve the problems mentioned as above, various methods, such as a method of introducing a high-temperature nitrogen gas (hot N2) into the exhaust pipe, a method of applying an inner heater, a method of applying a flexible heater, have been tried. Even when the above methods are applied, the precipitation of the powder may be just delayed but there is a limit to completely prevent the precipitation of the powder.

For example, FIG. 1 is a block diagram of a vacuum apparatus according to the related art.

A semiconductor manufacturing process proceeds in the form of using a reaction gas or a process gas in a process chamber 1, and a residual gas or reaction by-product, such as powder, is discharged through an exhaust line 2 after a predetermined process is completed.

As shown in FIG. 1, a nitrogen supplying apparatus 5 is mounted between a vacuum pump 3 and a scrubber 4 to heat nitrogen, which is an inert gas at room temperature, at a high temperature of about 200° C. to about 400° C. and supply the heated nitrogen to the exhaust line 2. According to the above-described method of supplying the high temperature nitrogen gas, moisture in the reaction gas evaporates, thereby preventing the powder from being generated, and smoothing a flow of fluid inside the pipe, so that the precipitation of the powder is suppressed.

However, according to the above-described method of supplying the high temperature nitrogen gas, since the device such as a heater for heating a nitrogen gas is installed at a rear end of the vacuum pump, it is difficult to maintain a uniform temperature throughout the pipe.

In addition, an amount of energy, which is consumed to heat the high temperature nitrogen gas in a short section, increases rapidly.

According to the method of applying the inner heater, the heater is mounted at a position in which the high temperature nitrogen gas supplying apparatus is mounted to increase thermal energy of a gas flowing out of the vacuum pump, thereby suppressing the powder to be generated and precipitated.

However, according to the above-described method of applying the inner heater, since the section for applying the heater inside the pipe is short, it is impossible to uniformly maintain the temperature of the entire pipe, and since the heater is directly exposed to the exhaust gas, a metal material surrounding the heater is corroded, thereby increasing the risk of fire.

According to the method of applying a flexible heater, the entire section between the vacuum pump and the scrubber is connected by a triple-structured flexible heater into which a mineral insulated (MI) heater is inserted.

According to the above-described method of applying the flexible heater, the back pressure increases when powder is precipitated inside the pipe, and the heater does not operate at all when a discharge temperature of a pump end rapidly rises to 500° C. or higher.

FIG. 2 is an exemplary view showing an installation state of a pipe to which the flexible heater is applied. FIG. 3(a) and FIG. 3(b) show exemplary views of a precipitated state of powder inside the pipe.

FIG. 3(a) shows an internal state of a section having a good fluidity in the pipe, and FIG. 3(b) shows an internal state of a section having precipitated powder due to sagging of the pipe.

As shown in FIG. 2, when the entire pipe 2 applied to the section between the vacuum pump and the scrubber is manufactured by applying a flexible heater with bellows, and both ends of the pipe 2 are installed and fixed by using a pair of fixing members H, a middle portion of the pipe 2 is sagged downward.

When a flow of the exhaust gas stagnates in the section in which the pipe 2 is sagged, the precipitation of powder is accelerated as shown in FIG. 3(b).

In addition, as the powder precipitated in the sagged section increases the back pressure, smooth exhaust activities are interfered, and accordingly an unnecessary load is applied to the vacuum pump, thereby shortening the PM cycle.

Accordingly, there is a need to develop a technology capable of completely preventing the powder from being precipitated inside the pipe.

(Patent Document 1) Korean Utility Model Registration No. 20-0469608 (Published on Oct. 23, 2013)

(Patent Document 2) Korean Patent Registration No. 10-1075170 (Published on Oct. 19, 2011)

### SUMMARY OF THE INVENTION

To solve the above-described problems, the present invention provides a flexible pipe that heats an exhaust gas to prevent powder from being precipitated inside a pipe.

In addition, the present invention provides a flexible pipe and an exhaust heating system with the same to prevent powder from being precipitated due to sagging of the flexible pipe and supply heat by limiting and concentrating only on a required section in the entire section of a pipe.

To achieve the above-mentioned objects, the flexible pipe according to the present invention includes: a plurality of fixed sections having a double pipe structure with a predetermined length and a straight shape; and at least one flexible section provided between the fixed sections and configured to be variable in length and shape, wherein the flexible section is provided as a triple structure including an outer bellows pipe having a corrugated pipe shape having peaks and valleys, an inner bellows pipe provided inside the outer bellows pipe, and an interlock pipe provided inside the inner bellows pipe, a heater is installed on an outer surface of an inner pipe of the fixed section having the double pipe structure in a fixed section applied to an input end connected to a vacuum pump among the fixed sections to intensively supply heat, and a pressure space is formed at a preset pressure in the fixed section and the flexible section after inserting and sublimating dry ice to shorten a heating time of an internal temperature and expand a holding time for allowing the internal temperature to be maintained and a cooling time for allowing the internal temperature to be decreased.

In addition, to achieve the above-mentioned objects, the exhaust heating system according to the present invention includes a flexible pipe for heating a fluid moving therein to have a preset temperature to prevent the powder from being precipitated, wherein the flexible pipe is configured by overlapping a plurality of pipes with each other and provided to have a length and a shape so as to be partially variable according to an applied section, and the flexible pipe is formed therein with a pressure space at a preset pressure after dry ice is inserted and sublimated, so as to shorten a heating time of an internal temperature and expand a holding time for allowing the internal temperature to be maintained and a cooling time for allowing the internal temperature to be decreased.

As described above, according to the flexible pipe and the exhaust heating system with the same of the present invention, the powder can be prevented from being precipitated inside the flexible pipe.

In other words, according to the present invention, after the fixed section is separated from the flexible section, the flexible section can be applied to a section to which a curved shape is applied, and the fixed section can be applied to the remaining section.

In particular, according to the present invention, the fixed section having the double structure is applied to the input end of the vacuum pump and the heater is intensively installed in the fixed section to intensively supply the heat to the input end of the vacuum pump, so that the exhaust gas supply temperature can be prevented from dropping significantly below the range between 180° C. and 200° C. that is a holding temperature range in the flexible pipe, and a heating time for raising a temperature of the input end to 180° C. or higher can be shortened.

In addition, according to the present invention, heat may be limitedly and intensively supplied only to the required portion by partially applying the flexible section having the triple structure, and applying the fixed section having the double structure to the remaining section so as to solve the problem of failing to intensively supply the heat to the portion configured as the interlock when the triple structure is constantly applied to the entire exhaust line, so that the heating efficiency can be improved in the exhaust line and the manufacturing cost can be reduced.

In addition according to the present invention, the heater is installed on the outer surfaces of the inner pipe and the inner bellows pipe to prevent the heater from being directly exposed to the exhaust gas, so that the risk of fire caused by corrosions of the heater and metal material surrounding the heater due to the exhaust gas can be prevented.

In addition, according to the present invention, it is possible to design to resist a corrosion generated in the semiconductor process by applying the inner bellows pipe having the double structure, a leak can be blocked once more in the outer bellows pipe even when the leak due to the corrosion of the inner bellows pipe occurs, and an occurrence of the leak can be detected in association with the PM cycle.

In addition, according to the present invention, the pressure space is formed inside the flexible pipe at a preset pressure, thereby shortening the rising time of the internal temperature in the exhaust heating system, so that the temperature holding time can be prolonged and the cooling time for decreasing the internal temperature can be prolonged.

Thus, according to the present invention, the gas is injected into an airtight space, thereby providing a heating effect and a thermal insulation effect, so that the efficiency of the exhaust heating system can be improved.

### BRIEF DESCRIPTION OF THE DRAWINGS

FIG. 1 is a block diagram of a vacuum apparatus according to the related art.

FIG. 2 is an exemplary view showing an installation state of a pipe to which a flexible heater is applied.

FIGS. 3(a)-3(b) show exemplary views of a precipitated state of powder inside the pipe.

FIG. 4 is a view showing a configuration of a vacuum apparatus according to the related art.

FIG. 5 is a view showing a configuration of an exhaust heating system to which a flexible pipe is applied according to the exemplary embodiment of the present invention.

FIG. 6 is a perspective view of the flexible pipe shown in FIG. 5.

FIG. 7 is a sectional view of the flexible pipe.

FIGS. 8 and 9 are enlarged views of portions A and B shown in FIG. 7.

FIG. 10 is a view showing a temperature measurement point in an exhaust line.

FIG. 11 is a view showing the results of measuring a temperature distribution for each point shown in FIG. 10.

FIG. 12 is a graph showing a triple point of dry ice.

FIG. 13 is a graph defining a heating time of the flexible pipe.

FIG. 14 is a graph of measuring a temperature of a flexible pipe having a set pressure by introducing dry ice into a pressure space.

FIGS. 15 and 16 are sectional views of a flexible pipe according to another embodiment of the present invention.

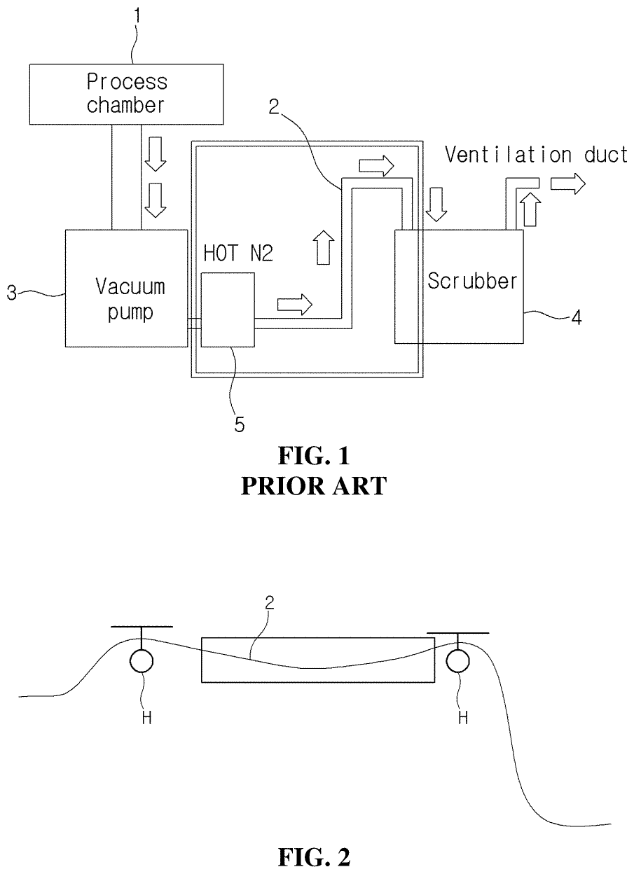

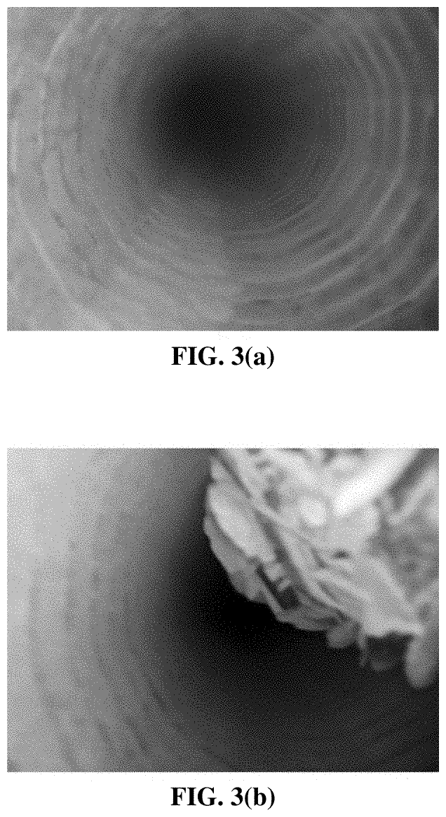

### DETAILED DESCRIPTION OF THE INVENTION

Hereinafter, a flexible pipe and an exhaust heating system with the same according to a preferred embodiment of the present invention will be described with reference to the accompanying drawings.

Hereinafter, the terms indicating directions such as “left”, “right”, “front”, “rear”, “upper” and “lower” are defined to indicate directions based on a status shown in drawings, respectively.

It should be noted that the embodiments of the present invention describes a flexible pipe applied to a vacuum apparatus of a semiconductor manufacturing equipment and an exhaust heating system with the same, but the present invention is not limited thereto, and may be modified to be applied to an exhaust line that discharges reactive gases generated in various product manufacturing processes for semiconductors, LCDs or the like.

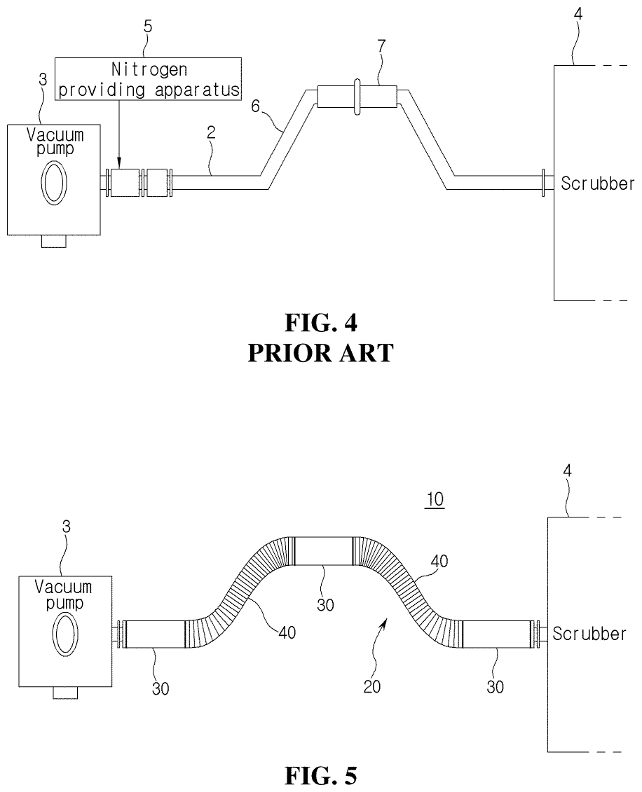

First, configurations of the vacuum apparatus applied to the semiconductor manufacturing equipment according to the related art will be described with reference to FIG. 4.

FIG. 4 is a view showing a configuration of a vacuum apparatus according to the related art.

In the vacuum apparatus applied to the semiconductor manufacturing equipment according to the related art, a length and a shape of the exhaust line 2 connected between an output end of the vacuum pump 3 and the scrubber 4 may be different according to features of each manufacturer.

For example, the exhaust line 2 may have a length of about 2 meters, and may be configured in a straight line.

Meanwhile, the exhaust line 2 may be elongated to have a length of about 4 meters to about 8 meters or more due to combinations of various pumps in the LCD or semiconductor manufacturing process, and may be configured to have a severe flexion so as to provide a bent portion 6 bent into various shapes such as an inverted ‘U’ shape, laterally inverted ‘L’ shape, reversed ‘L’ shape, or the like in a middle thereof as shown in FIG. 4.

In other words, the vacuum apparatus according to the related art is configured such that an exhaust pressure reduction module and a nitrogen supplying apparatus 5 for supplying high temperature nitrogen are installed to a discharge end side of the vacuum pump 4 in the exhaust line 2 provided with bellows and formed with the bent portion 6 in the middle thereof, and a heating jacket 7 is installed to the bent portion 6.

The vacuum apparatus 1 according to the related art configured as described above is provided as a combination type by applying the heating jacket 7 and the nitrogen supply apparatus 5 on the exhaust pipe to increase leak points, thereby increasing management points during product construction and management work.

In addition, the vacuum apparatus 1 according to the related art may cause an environmental pollution due to the gas leak, generate heat loss at connection portions and contact surfaces, and accumulate by-products on the bellows and flanges.

In addition, the vacuum apparatus 1 according to the related art may have difficulty in uniform heat distribution due to properties of the heating jacket 7; take longer time required for construction work due to sequential constructions; and cause short circuit or disconnection when jacket and heating wire are damaged.

Accordingly, the present invention is applied with an exhaust heating system 10 for preventing powder from being precipitated inside the pipe in order to solve the above problems even when the exhaust line is long or severely curved.

The configurations of the exhaust heating system according to exemplary embodiments of the present invention will be described in detail with reference to FIGS. 5 to 9.

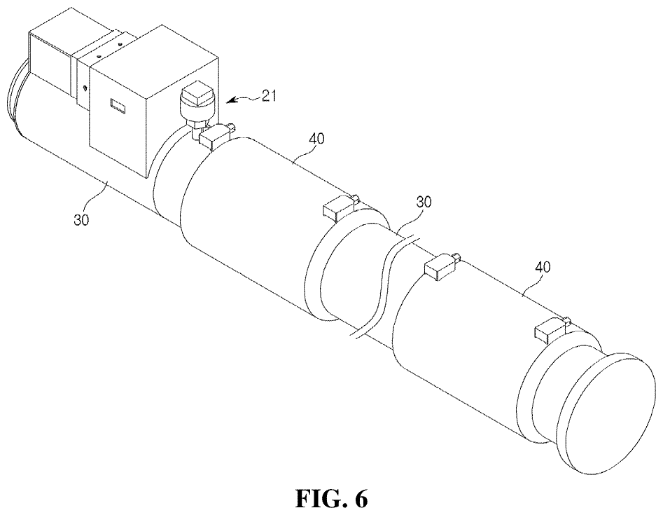

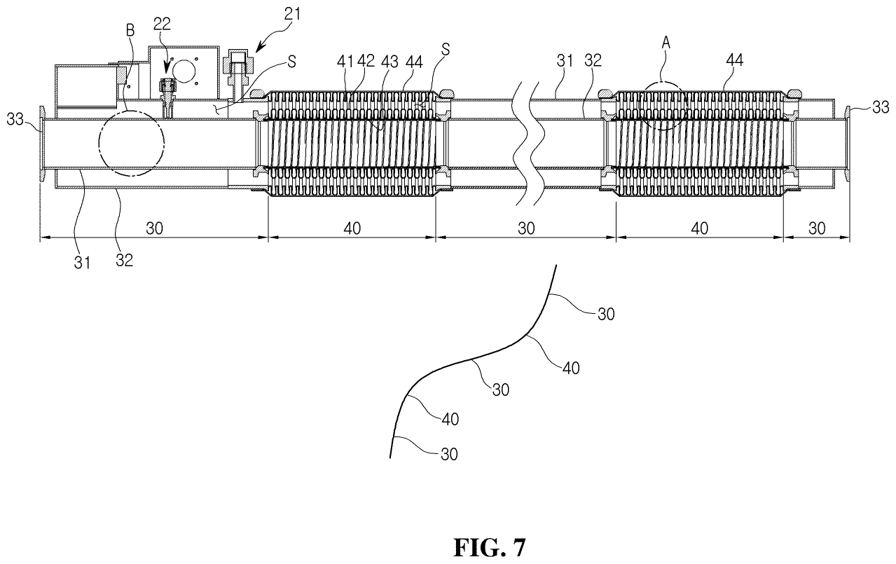

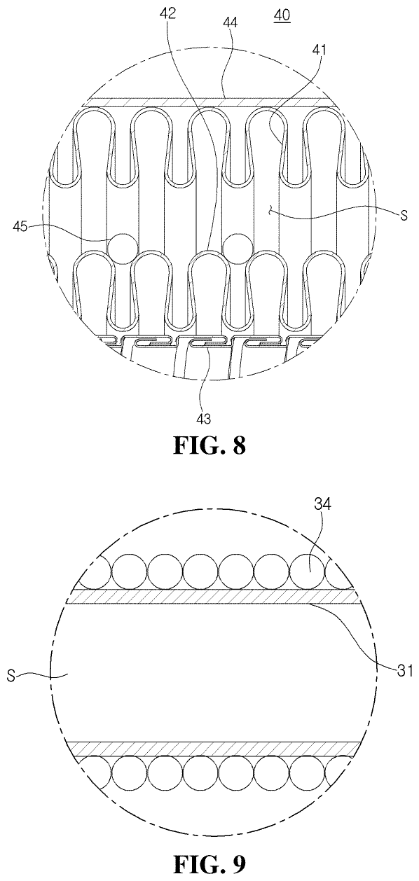

FIG. 5 is a view showing a configuration of an exhaust heating system to which a flexible pipe is applied according to the exemplary embodiment of the present invention. FIG. 6 is a perspective view of the flexible pipe shown in FIG. 5. In addition, FIG. 7 is a sectional view taken along line X-X′ shown in FIG. 6. FIGS. 8 and 9 are enlarged views of portions A and B shown in FIG. 7, respectively.

The exhaust heating system 10 to which the flexible pipe is applied according to a preferred embodiment of the present invention connects the vacuum pump 3 to the scrubber 4 as shown in FIGS. 5 and 6. To this end, the exhaust heating system 10 is configured by overlapping a plurality of pipes with each other, and configured to have a length and a shape so as to be partially variable according to an applied section. In addition, the exhaust heating system 10 is provided with a flexible pipe 20 in which a gas is injected at a preset pressure between a plurality of pipes to form a pressure space having a pressure higher than the set pressure.

Since the scheme of supplying nitrogen to the flexible pipe 20 is not applied to the present embodiment, the nitrogen supplying apparatus 5 is removed from the semiconductor manufacturing equipment shown in FIG. 2.

The flexible pipe 20 according to an embodiment of the present invention may include a plurality of fixed sections 30 having a double pipe structure with a constant length and a straight shape, and at least one flexible section 40 provided between the fixed sections 30 and configured to be variable in length and shape.

For example, in the present embodiment, configurations of a flexible pipe 20 including three fixed sections 30 and two flexible sections 40 will be described.

It should be noted that the present invention is not limited thereto and the number of the fixed section 30 and the flexible section 40 may be variously modified according to a shape of the entire pipe to which the flexible pipe 20 is applied.

Specifically, the fixed section 30 of the flexible pipe 20, as shown in FIGS. 6 to 8, may be provided as a double pipe structure including an inner pipe 31 and an outer pipe 32 manufactured to have diameters different from each other.

In addition, a pair of flanges 33 may be coupled, by welding, to outer ends of fixed sections 30 installed on both sides of the flexible pipe 10 respectively.

Meanwhile, one side, among the three fixed sections 30 shown in FIGS. 6 and 7, connected to the vacuum pump 3, for example, the fixed section 30 provided at a left end may be provided with a leak detection unit 21 for detecting a leakage of an exhaust gas through an inner bellows pipe 42 applied to the flexible section 40 to be described below, and a temperature detection unit 22 for sensing an internal temperature of the flexible pipe 20.

The leak detection unit 21 is connected to a pressure space S provided between the outer bellows pipe 41 and the inner bellows pipe 42 that are applied to the flexible section 40, and detects whether the exhaust gas is leaked through the inner bellows pipe 42.

The above leak detection unit 21 may be provided as a pressure sensor for detecting a pressure change in the pressure space S, or configured using a litmus test paper or solution that is changed in color by contact with the exhaust gas.

For example, a pressure of the pressure space S formed between the outer bellows pipe 41 and the inner bellows pipe 42 of the flexible pipe 20 rises up to about 2 bar by heat of the exhaust gas moving along the inside of the flexible pipe 20 in a use environment installed in a vacuum line of a general semiconductor manufacturing equipment in which the set pressure is not formed.

Thus, according to the present invention, the pressure change due to leakage in the flexible pipe may be detected by using the pressure sensor, and an occurrence of the leakage may be inspected by using the detection result.

The temperature detection unit 22 may be installed to come into contact with the inner pipe 31 connected to one end of the inner bellows pipe 42 and may include a temperature sensing sensor to detect a temperature change in the inner pipe 31.

Detection signals of the leakage detection unit 21 and the temperature detection unit 22 may be transmitted to a management terminal (not shown), and the management terminal may determine whether the leakage occurs by using the pressure or color change detected by the leak detection unit 21.

In addition, the management terminal may determine whether powder is precipitated in the flexible pipe 20 by using the temperature change detected by the temperature detection unit 22.

In other words, as a result of analyzing a product used in an actual vacuum apparatus, when powder is precipitated inside the pipe, the temperature of the pipe rises sharply to about 500° C. or higher.

In contrast, when the temperature of the pipe decreases, the amount of powder precipitated inside increases.

Accordingly, since a front end of the pipe connected to the vacuum pump 3 is heated to the temperature of about 500° C. or higher, the amount of powder precipitated at the front end of the pipe is relatively smaller than the amount precipitated at a rear end of the pipe.

In contrast, as the temperature decreases to about 150° C. toward a rear end of the pipe connected to the scrubber 4, the amount of powder precipitated at the rear end of the pipe becomes relatively larger than the amount of powder precipitated at a front end of the pipe.

Accordingly, in the present embodiment, since the precipitated amount of powder increases toward the rear end adjacent to the scrubber 4, the leak detection unit 21 and the temperature detection unit 22 may be installed to the rear end side of the flexible pipe 20.

Accordingly, the present invention can improve the thermal insulation and the anti-leakage performance of the flexible pipe, and can prevent the powder from being precipitated inside the flexible pipe.

Referring back to FIGS. 6 to 8, the flexible section 40 of the flexible pipe 20 may be provided as a triple structure including an outer bellows pipe 41 having a shape of a corrugated pipe having peaks and valleys, an inner bellows pipe 42 provided inside the outer bellows pipe 41, and an interlock pipe 43 provided inside the inner bellows pipe 42.

In the above flexible section 40, a braid 44 may be installed onto an outer side of the outer bellows pipe 41, and a heater 45 for heating a gas moving inside the interlock pipe 43 may be installed on an outer surface of the inner bellows pipe 42.

The heater 45 is integrally connected to the heater 34 in the fixed section 30, and the fixed section 30 and the pressure space S in the flexible section 40 are in association with each other. Accordingly, the leak detection unit 21 and the temperature detection unit 22 may detect the pressure and the temperature inside the pressure space S, and a controller (not shown) for operating the heaters 34 and 45 may control the temperature inside the pressure space S to be constantly maintained by turning on and off the heaters 34 and 45 according to the temperature detected by the temperature detection unit 22.

The braid 44 may function as a stopper for limiting changes in length and shape of the flexible section 40 due to increases in temperature and pressure of the flexible pipe 20.

The braid 44 may have a straight pipe shape or a curved shape at various angles to correspond to the length and shape of the flexible section 40 in a state in which the flexible pipe 20 is installed, and both ends of the braid 44 may be fixed to the outer surface of the outer bellows pipe 41 by using band members.

Thus, according to the present invention, the flexible section changeable in length and shape is applied between the fixed sections, so that the installation can be implemented in a portion for which the flexibility is required in the vacuum line.

In addition, according to the present invention the flexible section having the triple structure is applied, so that the entire pipe is easily maintained at a uniform temperature, the heater is not directly exposed to the exhaust gas, thereby removing the risk of fire, and the heat loss is the smallest compared to similar construction methods.

According to the test results, it is confirmed that the flexible pipe applied with the triple structure saves energy by about 30% or more.

Meanwhile, the inner bellows pipe 42 is shown as one bellows pipe in FIG. 8, but may be provided as a double structure.

For example, the inner bellows pipe 42 may include first bellows formed in a corrugated tubular shape having peaks and valleys and second bellows formed in a corrugated tubular shape having peaks and valleys and provided inside the first bellows.

The first bellows and the second bellows are may be formed into a corrugated tubular shape having peaks and valleys through a hydro-forming process in a state in which an inner pipe is inserted and coupled inside an outer pipe formed of a metal or synthetic resin material.

Accordingly, the present invention may be design to resist the corrosion generated in the semiconductor process by applying the inner bellows pipe having the double structure, the leak can be blocked once more in the outer bellows pipe even when a leak due to the corrosion of the inner bellows pipe occurs, and an occurrence of the leak can be detected in association with the PM cycle.

The interlock pipe 43 is manufactured by bending strip-shaped metal plates to form a specific shape and connecting the formed strip-shaped metal plates to each other while spirally rotating about an axis.

An interlocking structure refers to interconnection between the formed metal plates. Since the interlock pipe 43 configured in the above manner is installed in adverse conditions together with the exhaust line for discharging a gas having the high temperature and high pressure, the interlock pipe 43 is required to have the flexibility for preventing a damaged due to vibration. In addition, the interlock pipe 43 is required to be prevented from being broken due to resonance, to have no clearance to prevent the leakage of the exhaust gas, not to be cured when exposed to heat, to have resistance against various stresses such that it cannot be easily broken due to an external impact, and to be prevented from being easily broken due to aging.

Accordingly, in the present embodiment, a flexible hose having a quadruple structure may be configured to connect the vacuum pump 3 to the scrubber 4, and a straight shape or a curved shape may be formed according to an arranged state of the vacuum pump 3 and the scrubber 4.

As shown in FIG. 8, the heater 45 may be provided as a heating cable having a mineral insulated layer on an inner surface thereof, and may be installed after wound on the outer surface of the inner bellows pipe 42 at regular intervals.

The above heater 45 is supplied with power to heat the flexible pipe 20, so that the exhaust gas moving through the flexible pipe 20 may be heated to a preset temperature, for example, about 180° C.

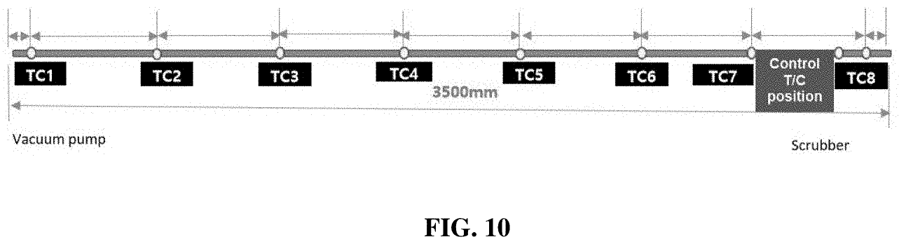

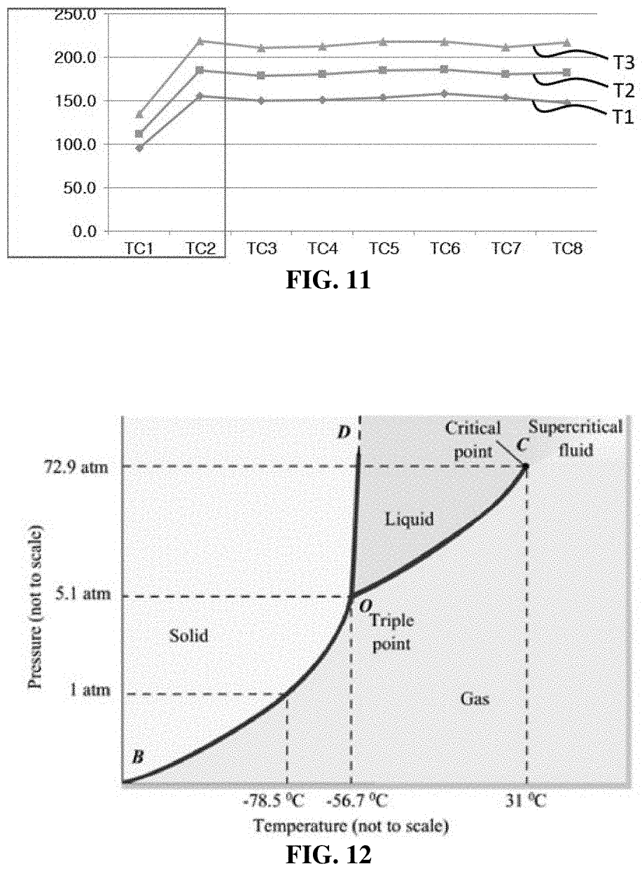

Meanwhile, FIG. 10 is a view showing a temperature measurement point in an exhaust line. FIG. 11 is a view showing the results of measuring a temperature distribution for each point shown in FIG. 10.

FIG. 10 illustrates eight temperature measurement points TC1 to TC8 set at regular intervals on the exhaust line having a total length of 3500 mm.

In addition, FIG. 11 shows a temperature distribution T1 measured 60 minutes after the temperature of the pipe reaches 120° C., a temperature distribution T2 measured 60 minutes after the temperature of the pipe reaches 150° C., and a temperature distribution T3 measured 60 minutes after the temperature of the pipe reaches 180° C.

In FIGS. 10 and 11, the heat is required to be concentrated at the input end of the vacuum pump to minimize the effect of the exhaust gas temperature.

However, when the triple structured flexible pipe is applied to the entire exhaust line, there is a limit to concentrate the heat at the input end of the vacuum pump.

Therefore, according to the present invention, the fixed section is separated from the flexible section, the flexible section is applied to a section to which the curved shape is applied, and the fixed section is applied to the remaining sections.

In addition, according to the present invention, the fixed section 30 having the double structure may be applied to the input end of the vacuum pump, and the heater 34 may be installed in the fixed section 30 so that the heat is intensively supplied.

In other words, according to the present invention as shown in FIG. 9, the heater 45 provided with the heating cable may be intensively installed on the outer surface of the inner pipe 31 in the fixed section 30 applied to the input end of the vacuum pump that requires the heat concentration.

The heater 34 may be installed by minimizing the winding intervals around the outer surface of the inner pipe 31 and maximizing the number of windings.

Thus, according to the present invention, the exhaust gas supply temperature can be prevented from significantly dropping below the range between 180° C. and 200° C., which is a holding temperature in the flexible pipe in the input end of the vacuum pump, and the heating time for raising a temperature of the input end to 180° C. or higher can be shortened.

In other words, the present invention can solve the problem of failing to intensively supply the heat to the portion configured as the interlock when the triple structure is uniformly applied to the entire exhaust line.

Thus, according to the present invention, the flexible section having the triple structure is partially applied such that the heat can be limitedly and intensively supplied only to the required portion, and the fixed section having the double structure is applied to the remaining section, so that the heating efficiency can be improved in the exhaust line and the manufacturing cost can be reduced.

In addition, according to the present invention, the heater is installed on the outer surfaces of the inner pipe and the inner bellows pipe to prevent the heater from being directly exposed to the exhaust gas, so that the risk of fire caused by corrosions of the heater and metal material surrounding the heater due to the exhaust gas can be prevented.

Particularly, in the present embodiment, the set pressure is formed by injecting a preset gas into the pressure space S, so that the raising time for raising the temperature of the input end to the preset temperature can be shortened and the descending temperature of the input end is delayed, thereby increasing the overall temperature holding time.

The gas may be provided with a gas having low explosive and flammable properties to prevent explosion due to chemical reaction with the exhaust gas conveyed through the inside of the flexible pipe.

Accordingly, in the present embodiment, the atmosphere may be pressurized and injected into the pressure space S.

Meanwhile, in the present embodiment, the set pressure may be formed by pressurizing and injecting carbon dioxide (CO2) having a long half-life of about 5000 years or more, in which the number of molecules is reduced by half due to molecular structural changes in a space hermetical compared to the atmosphere, or by sublimating dry ice added to the pressure space S.

The set pressure may be set to +0.05 bar or higher compared to the atmospheric pressure.

FIG. 12 is a graph showing a triple point of the dry ice.

As shown in FIG. 12, dry ice sublimes into a gas upon −78.5° C. or higher under the atmospheric pressure (1 atm=1.01325 bar).

Accordingly, the amount of dry ice injected into the pressure space S may be calculated using the ideal gas state equation: PV=nRT, PV=wRT/M, wherein, P is a pressure, V is a volume, n is the number of gas particles, R is an ideal gas constant, T is a temperature, and M is the molar mass.

For example, the amount of dry ice for increasing the atmospheric pressure after the dry ice is put in a hermetic space at a room temperature of 25° C. and entirely vaporized corresponds to 1*V=w(0.08205*298)/44 when 44 g/mol the molecular weight of carbon dioxide are applied into the ideal gas equation, and thus the mass (w) of the dry ice is V/0.55570.

Accordingly, when 220 g of dry ice is put into the hermetic space (25° C. and 1 L) and the dry ice is entirely vaporized, the final pressure in the hermetic space may be calculated through the following process.

In other words, since the molecular weight of carbon dioxide is 44.0095 g/mol, 220 g of dry ice becomes 5 mol.

When the above value is applied to the ideal gas equation, P is nRT/V and R is 0.08205 L atm/mol K, wherein, n=5, R=0.08205, T=273+25=298, and V=1.

Accordingly, the final pressure (P) in the hermetic space is 122 atm (=12.159 bar).

Accordingly, when the set pressure of the pressure space S is set to +0.05 bar to +0.1 bar compared to the atmospheric pressure, the injection amount of dry ice is about 12 g to 24 g subject to 6 L of the volume in the pressure space S.

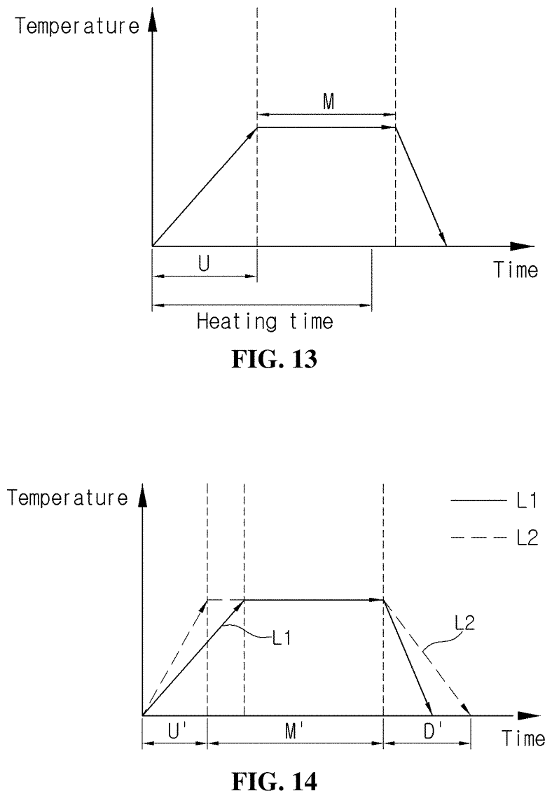

For example, FIG. 13 is a graph defining a heating time of the flexible pipe, and FIG. 14 is a graph of measuring a temperature of a flexible pipe having a set pressure by introducing dry ice into a pressure space. Table 1 shows the results illustrated in FIG. 14.

TABLE 1

| | Heating time | Holding time | Cooling time |
|---|---|---|---|
| Atmospheric | 30 min | 50 min | 20 min |
| pressure state | | | |
| Dry ice | 20 min | 60 min | 40 min |

FIG. 14 shows a temperature curve L1 measured at atmospheric pressure in the pressure space S and a temperature curve L2 measured after injecting dry ice into the pressure space S.

As shown in FIG. 13, when the exhaust gas is transferred while the flexible pipe 20 according to the embodiment of the present invention is applied to the exhaust heating system 10, the temperature inside the flexible pipe 20 may be divided into a rising time U rising to a preset temperature, such as about 120° C., according to the heat of the exhaust gas, a holding time M maintained at the set temperature, and a cooling time D for lowering the internal temperature. The heating time U and the holding time M correspond to a heating time H for heating the exhaust gas by operating the heater 34.

Accordingly, in the case of the flexible pipe 20 formed with the set pressure by injecting dry ice into the pressure space S, it can be seen that the holding time M′ increases and the cooling time D′ also increases when the heating time U′ is shorter than the atmospheric pressure state as shown in FIG. 14.

Thus, according to the present invention, the pressure space is formed at a preset pressure inside the flexible pipe to shorten the raising time for raising the internal temperature in the exhaust heating system, so that the time for keeping the temperature can be prolonged, and the cooling time for allowing the internal temperature to decrease can also be prolonged.

Thus, according to the present invention, the efficiency of the exhaust heating system can be maximally improved.

Meanwhile, FIG. 14 and Table 1 show the measurement results in a heated state by operating the heater, in which the same result is confirmed that the heating time is shortened and the holding time and the cooling time are increased even when the heater is not operated.

In addition, it was confirmed that the temperature inside the pressure space S may be temporarily lowered when dry ice is injected, but the temperature returned to the room temperature after the exposure time has elapsed for about 30 minutes. Accordingly, an influence of the temperature change may be neglected when the dry ice is injected into the pressure space S of the flexible pipe 20.

In addition, according to the present invention, the set pressure is formed by injecting the dry ice sublimated into a gas at room temperature in the pressure space into the pressure space, or by injecting a gas such as carbon dioxide, so that the heating time for increasing the temperature inside the flexible pipe may be shortened, and the holding time for maintaining the set temperature and the cooling time for decreasing the temperature may be increased.

Thus, according to the present invention, the gas is injected into an airtight space, thereby providing a heating effect and a thermal insulation effect, so that the efficiency of the exhaust heating system can be improved.

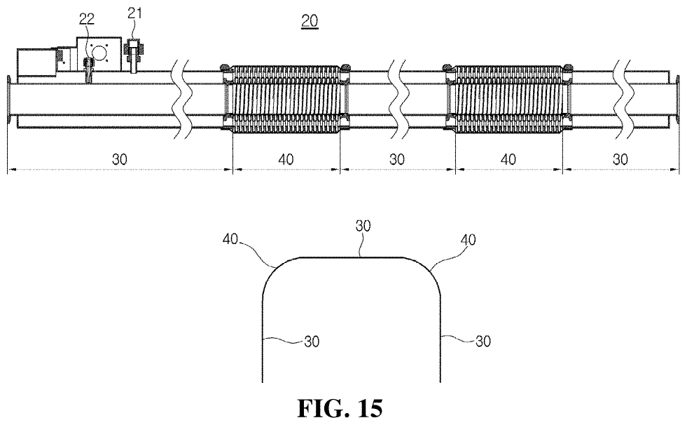

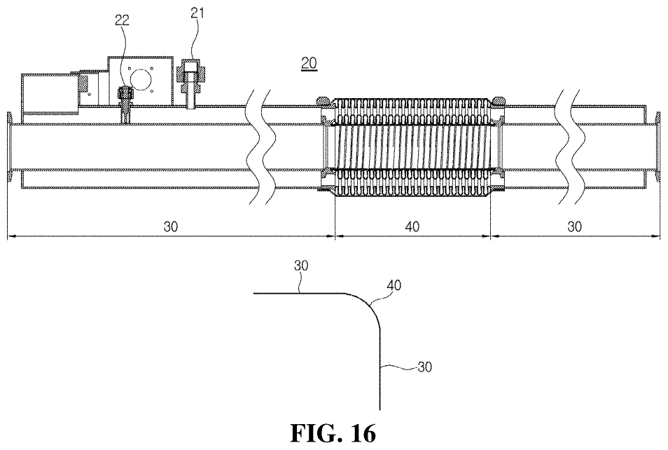

Meanwhile, FIGS. 15 and 16 are sectional views of a flexible pipe according to another embodiment of the present invention.

As shown in FIG. 15, the flexible pipe 20 according to another embodiment of the present invention is configured such that the lengths of the fixed section 30 and the flexible section 40 may be adjusted to be increased or decreased according to the length of the section installed with the flexible pipe 20.

In addition, as shown in FIG. 16, the flexible pipe 20 according to still another embodiment of the present invention is configured such that the numbers of the fixed section 30 and the flexible section 40 may be adjusted to be increased or decreased according to the length and the shape of the section installed with the flexible pipe 20.

Accordingly, the present invention may be applied to section having various shapes by adjusting the lengths, shapes and numbers of the fixed section and the flexible section according to the length and shape of the section installed with the flexible pipe, and applying the flexible section to the curved portion.

Although the invention implemented by the inventor of the present invention has been described in detail according to the above embodiments, the present invention is not limited to the embodiments and various modifications are available within the scope without departing from the invention.

The present invention may be applied to the technology for preventing powder from precipitated inside the flexible pipe.

1. A flexible pipe comprising:
a plurality of fixed sections having a double pipe structure with a predetermined length and a straight shape; and
at least one flexible section provided between the fixed sections and configured to be variable in length and shape, wherein
the flexible section is provided as a triple structure including an outer bellows pipe having a corrugated pipe shape having peaks and valleys, an inner bellows pipe provided inside the outer bellows pipe, and an interlock pipe provided inside the inner bellows pipe,
a heater is installed on an outer surface of an inner pipe of the fixed section having the double pipe structure in a fixed section applied to an input end connected to a vacuum pump among the fixed sections to intensively supply heat, and
a pressure space is formed at a preset pressure in the fixed section and the flexible section after inserting and sublimating dry ice to shorten a heating time of an internal temperature and expand a holding time for allowing the internal temperature to be maintained and a cooling time for allowing the internal temperature to be decreased.

2. The flexible pipe of claim 1, wherein the outer bellows pipe is installed on an outer side thereof with a braid for limiting alterations in length and shape of the flexible pipe, and the inner bellows pipe is installed on an outer surface thereof with a heater for heating gas moving inside the interlock pipe.

3. An exhaust heating system comprising a flexible pipe configured according to claim 1 to heat a fluid moving therein to have a preset temperature to prevent the powder from being precipitated, wherein
the flexible pipe is configured by overlapping a plurality of pipes with each other and provided to have a length and a shape so as to be partially variable according to an applied section, and
the flexible pipe is formed therein with a pressure space at a preset pressure after dry ice is inserted and sublimated, so as to shorten a heating time of an internal temperature and expand a holding time for maintaining the internal temperature and a cooling time for decreasing the internal temperature.
